(19) United States
(12) Patent Application Publication
(10) Pub. No.: US 2012/0300414 A1
(43) Pub. Date: Nov. 29, 2012

(54) MULTI-FUNCTION DUMMY CARD

(75) Inventor: CHIH-PIN CHEN, Tu-Cheng (TW)

(73) Assignee: HON HAI PRECISION INDUSTRY CO., LTD., Tu-Cheng (TW)

(21) Appl. No.: 13/195,032

(22) Filed: Aug. 1, 2011

(30) Foreign Application Priority Data
May 24, 2011 (TW) 100118045

(51) Int. Cl. H05K 7/00; H05K 1/18

(52) U.S. Cl. 361/737

(57) ABSTRACT

A multi-function dummy card inserted in an electronic card slot of an electronic device includes a lower cover, a main board fixed on the lower cover, an upper cover fixed on the main board, and a first button received into the upper cover. The lower cover includes a laser. The main board includes a chargeable battery for providing power for the laser. When the first button is pressed to contact the main board, the main board generates a first signal to turn on the laser.

### BACKGROUND

1. Technical Field

The present disclosure relates to dummy cards and, particularly, to a dummy card with multiple functions.

2. Description of Related Art

Many electronic devices such as notebook computers include a dummy card which is used to prevent dust from entering the device and to improve appearance of the device. However, the dummy card with only those functions is too limited in usage.

### BRIEF DESCRIPTION OF THE DRAWINGS

FIG. 1 is an isometric view of a dummy card for being inserted into an electronic device, in accordance with an exemplary embodiment.

FIG. 2 is an isometric view of the dummy card of FIG. 1.

FIG. 3 is an isometric view of the dummy card of FIG. 1, viewed from another aspect.

FIG. 4 is an exploded view of the dummy card of FIG. 1.

### DETAILED DESCRIPTION

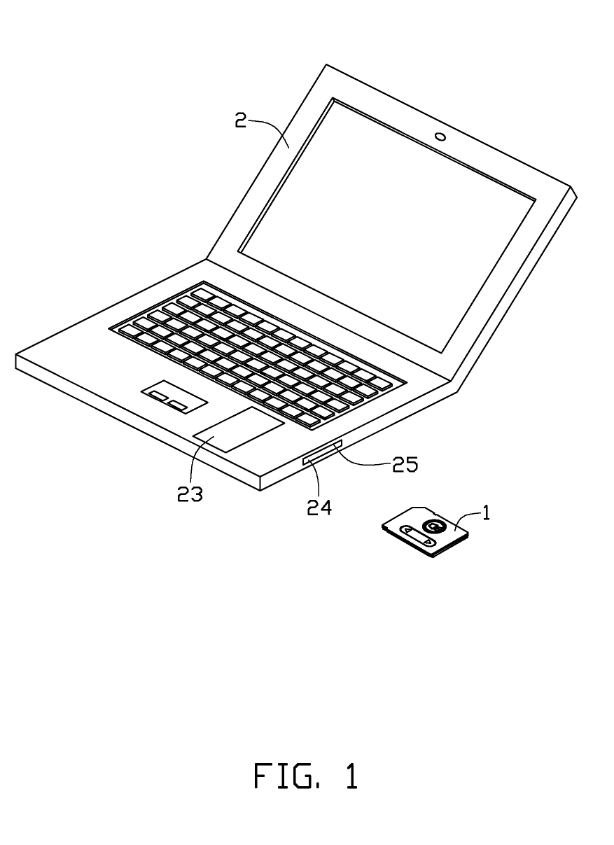

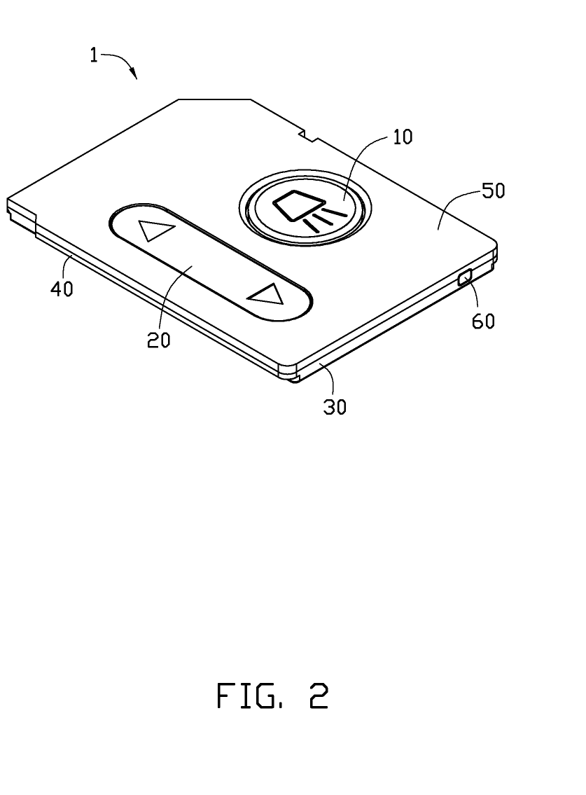

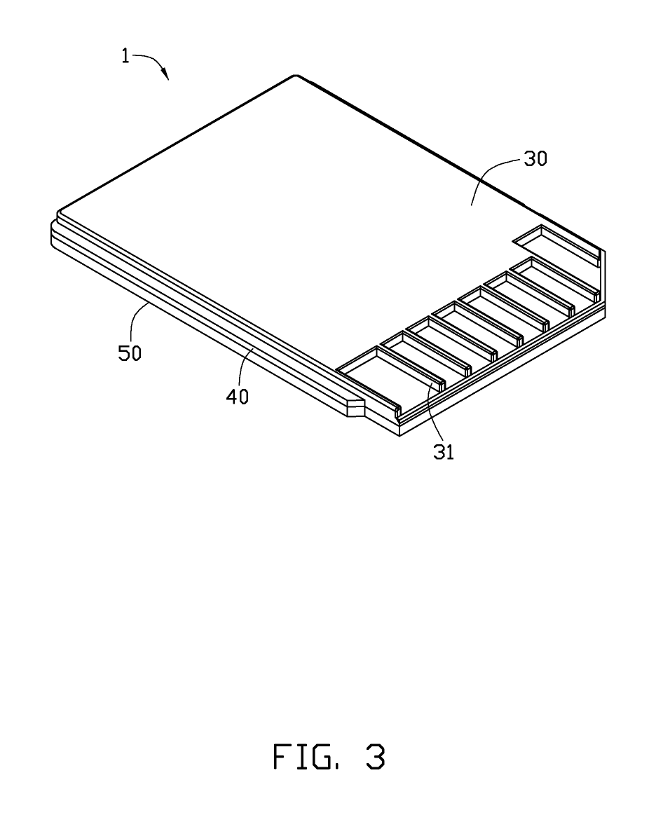

Referring to FIGS. 1-3, a multi-function dummy card 1 is provided. The dummy card 1 can be inserted into an electronic card connector 25 of an electronic device 2. In one embodiment, the device 2 may be a notebook computer, digital photo frame or other such device.

The dummy card 1 includes a lower cover 30, a main board 40 mounted on the lower cover 30, an upper cover 50 mounted on the main board 40, and a first button 10 received in the upper cover 50. A laser 60 is mounted on the lower cover. The first button 10 can be manually pushed to contact the main board 40, after the button 10 contacts the main board 40; the main board 40 generates a first signal to turn on the laser 60, which can be used as a laser pointer by a user. In order to better understand the disclosure, an exemplary embodiment is described in detail.

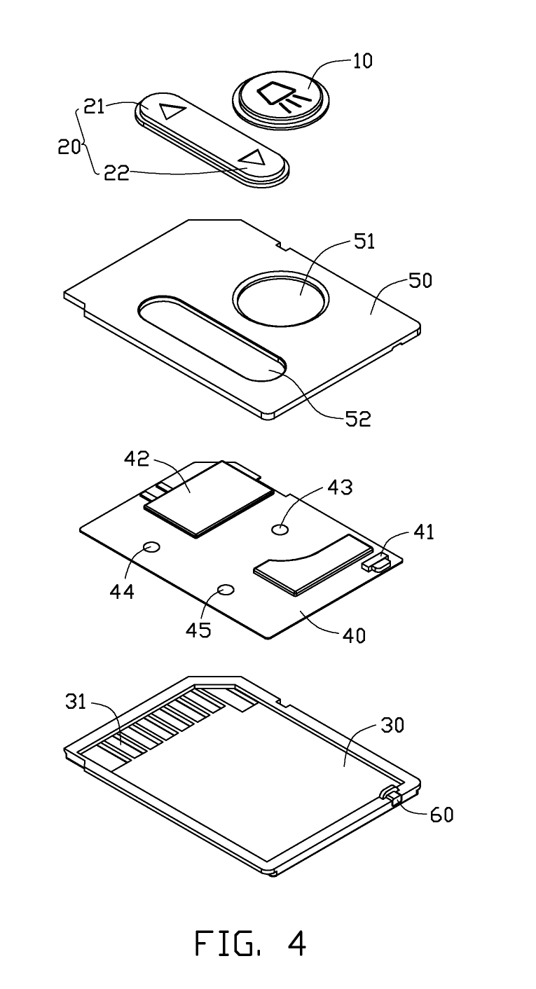

Referring to FIG. 4, there are also a number pins 31 mounted on the lower cover 30.

The electronic device 2 defines a slot 24 and a second BLUETOOTH module 23. The electronic card connector 25 is received in the slot 24.

The upper cover 50 defines a first perforation 51 and a second perforation 52 extending therethrough. The first button 10 is received into the first perforation 51.

The dummy card 1 further includes a second button 20 received in the second perforation 52. The second button 20 includes an up button 21 and a down button 22.

The main board 40 includes a first BLUETOOTH module 42 to pair with the second BLUETOOTH module 23, a chargeable battery 41, a first contact 43 aligned with the first perforation 51, and a second contact 44 and a third contact 45 aligned with the second perforation 52. The chargeable battery 41 is configured for providing power for the laser 60. When the first button 10 is pressed to contact the first contact 43, the first contact 43 will generate the first signal to control the laser 60 to emit the light. When the up button 21 is pressed to contact the second contact 44, the second contact 44 will generate a second signal, which in this embodiment, controls advancing to a next page of a document being viewed on a screed of the electronic device 2. When the down button 22 is pressed to contact the third contact 45, the third contact 45 will generate a third signal, which in this embodiment will change the document view to a preceding page. In other embodiments, the signals generated by the buttons 21, 22 may initiate other events.

To assemble the dummy card 1, the main board 40 is fixed on the lower cover 30. The first button 10 and the second button 20 is respectively placed into the first perforation 51 and the second perforation 52. The upper cover 50 is fixed on the main board 40.

When the dummy card 1 is not being used it can be stored in the slot 24, where the pins 31 contact the electronic card connector 25, allowing charging of the chargeable battery 41.

To use the slot 24 the dummy card 1 is removed and set aside. To use the dummy card 1, the dummy card 1 is taken out of the slot 24, and the user can press the first button 10 to turn on the laser 60, or press the up or down buttons 21, 22 to generate the second signal or the third signal to control the electronic device 2 to implement the corresponding operations.

Although the present disclosure has been specifically described on the basis of the embodiments thereof, the disclosure is not to be construed as being limited thereto. Various changes or modifications may be made to the embodiments without departing from the scope and spirit of the disclosure.

What is claimed is:

1. A multi-function dummy card for being inserted into an electronic card slot of an electronic device, the dummy card comprising:
a lower cover comprising a laser;
a main board fixed on the lower cover, and comprising a chargeable battery for providing power for the laser;
an upper cover fixed on the main board; and
a first button received in the upper cover;
wherein when the first button is pressed to contact the main board, the main board generates a first signal to turn on the laser.

2. The dummy card as described in claim 1, further comprising a second button received in the upper cover, wherein the main board comprises a first BLUETOOTH module to pair with a second BLUETOOTH module of the electronic device, when the second button is pressed to contact the main board, the main board generates a second signal or a third signal to control the electronic device to implement a corresponding operation.

3. The dummy card as described in claim 1, wherein the lower cover comprises a plurality of pins, when the dummy card is inserted into a slot of the electronic device, the plurality of pins contact the electronic card, and the electronic device charges for the chargeable battery.

4. The dummy card as described in claim 2, wherein the upper cover defines a first perforation and a second perforation, the first button is received in the first perforation, and the second button is received in the second perforation.

5. The dummy card as described in claim 4, wherein the main board further comprises a first contact aligned with the first perforation, and a second contact and a third contact aligned with the second perforation, the second button comprises a up button and a down button, when the first button is pressed to contact the first contact, the first contact generates the first signal to turn on the laser, when the second button is pressed to contact the second contact or the third contact, the second contact or the third contact generates the second signal or the third signal to control the electronic device to implement the corresponding operation.

6. A multi-function dummy card being inserted into an electronic card slot of an electronic device, the dummy card comprising:
a lower cover;
a main board fixed on the lower cover, and comprising a first BLUETOOTH module to pair with a second BLUETOOTH module of the electronic device;
an upper cover fixed on the main board;
a second button received in the upper cover;
wherein when the second button is pressed by to contact the main board, the main board generates a second signal or a third signal to control the electronic device to implement a corresponding operation.
